(19) United States
(12) Patent Application Publication
(10) Pub. No.: US 2026/0303106 A1
(43) Pub. Date: Oct. 1, 2026

(54) CORRECTION OF RESIDUE AMPLIFIER NON-LINEARITY IN PIPELINED ANALOG-TO-DIGITAL CONVERTERS

(71) Applicant: Texas Instruments Incorporated, Dallas, TX (US)

(72) Inventors: Nithin Gopinath, Bangalore (IN); Prabhansh Pandey, Singrauli (IN); Ashwin Ravi, Bangalore (KA); Neeraj Shrivastava, Bangalore (IN); Samriddh Bhalla, Bangalore (IN); Deep Satra, Bangalore (IN); Kevin Dharemsh Arvadia, Surat (IN)

(21) Appl. No.: 19/095,257

(22) Filed: Mar. 31, 2025

(51) Int. Cl. H03M 1/06

(52) U.S. Cl. CPC H03M 1/0604

(57) ABSTRACT

An analog-to-digital converter (ADC) includes a first ADC stage that generates a first digital signal and a residue signal, responsive to an input signal plus an added signal at a known level. A residue amplifier amplifies the residue signal from the first ADC stage, and a second ADC stage has an input coupled to the output of the residue amplifier. A correction circuit applies a correction at the output of the second ADC stage to produce a second digital signal. A selected input level detector outputs a signal indicating that the input signal is at a selected input level. Each of a plurality of accumulators accumulates the corrected output of the second ADC stage for one of a plurality of added signal levels responsive to the signal from the selected input level detector. Regression circuitry generates the correction applied by the correction circuit responsive to the accumulator contents.

### BACKGROUND

This specification relates to data conversion. More particularly, this specification relates to multi-stage, or pipelined, analog-to-digital converters (ADCs).

The application of modern signal processing systems to the physical world often involves the conversion of signals in the analog domain to digital data. Analog-to-digital converters (ADCs) refer to the system components that perform this conversion. Modern ADCs are implemented in a variety of architectures and approaches, providing a wide range of ADC performance in metrics such as resolution, bandwidth, precision, power consumption, and operating temperature range. One may select from among this variety of ADC approaches according to the intended system application and function, such as in data acquisition, communications, instrumentation, signal processing interfacing, and the like.

One ADC approach is referred to as the pipelined type of ADC. In a pipelined ADC, a first analog stage, for example a “flash” ADC stage, converts an analog input sample into one or more digital bits. This digital output from the first stage is applied to a digital-to-analog converter (DAC). The difference between the output of this DAC and the analog input sample constitutes a residue signal, analogous to a remainder from the first analog-to-digital conversion, which is applied to a next ADC stage in the pipeline. A residue amplifier applies a gain to the residue signal from the first ADC stage, in order to reduce the impact of noise at the next ADC stage in the pipeline.

### SUMMARY

According to an example, an analog-to-digital converter (ADC) includes a first ADC stage having first and second inputs, a digital output and a residue output. A signal generator has an output coupled to the second input of the first ADC stage. A selected input level detector has an input coupled to the first input of the first ADC stage. A residue amplifier has an input coupled to the residue output of the first ADC stage, and a second ADC stage has an input coupled to an output of the residue amplifier. A correction circuit is coupled to an output of the second ADC stage. Accumulator circuitry has an input coupled to an output of the selected input level detector. The accumulator circuitry includes a plurality of accumulators, each having an input coupled to an output of the correction circuit and associated with one of a plurality of signal levels generated by the signal generator circuit. Regression circuitry has an input coupled to an output of the accumulator circuitry, and an output coupled to an input of the correction circuitry.

According to another example, an analog-to-digital converter includes a signal generator circuit capable of providing a signal at a plurality of known signal levels, and a first ADC stage capable of providing a first digital signal and a residue signal responsive to an input signal and a dither signal. A selected input level detector is capable of providing a first signal indicating that the input signal is at a selected input level. A residue amplifier is capable of amplifying the residue signal from the first ADC stage, and a second ADC stage has an input coupled to the output of the residue amplifier. A correction circuit is capable of applying a correction at the output of the second ADC stage to produce a second digital signal. Accumulator circuitry includes a plurality of accumulators, each accumulating the corrected output of the second ADC stage for one of the plurality of known added signal levels responsive to the first signal from the selected input level detector. Regression circuitry is capable of generating the correction applied by the correction circuit responsive to the contents of the plurality of accumulators.

According to another example, a method includes, for each of a plurality of input samples, generating a signal at one of a plurality of known signal levels; at a first analog-to-digital converter (ADC) stage, converting a summed signal of an input sample and the known signal level to m output bits and a residue; and at a second ADC stage, and converting the residue from the first ADC stage to a second stage output. The method further includes adding the second stage output to the contents of the one of a plurality of accumulators associated with the known signal level responsive to the input sample being near a selected input level. A nonlinear error correction is applied to the second stage output based on the contents of the plurality of accumulators.

Examples of technical advantages enabled by one or more of the described examples include reducing integral non-linearity (INL) in pipelined ADCs, as provided by residue amplifiers operating at low power supply voltages, low power consumption, and with reduced chip area. High-performance and low power ADC circuits can be provided without compromises in spurious-free dynamic range (SFDR) and signal-to-noise ratio (SNR).

Other example technical advantages enabled by this disclosure are apparent to those of ordinary skill in the art having reference to the following specification together with its drawings.

### BRIEF DESCRIPTION OF THE DRAWINGS

FIG. 1 is an electrical diagram, in block form, of an analog-to-digital converter (ADC) circuit according to the described examples.

FIG. 2 illustrates plots of residue amplifier output in the ideal case, and in a case with non-linearities from a residue amplifier.

FIGS. 3A and 3B are plots of linear and non-linear error over dither levels around a selected input level.

FIG. 4 is an electrical diagram, in block form, of an example stochastic comparator in the ADC of FIG. 1.

FIG. 5 is an electrical diagram, in block form, of example accumulator circuitry in the ADC of FIG. 1.

FIG. 6 is a flow diagram illustrating a method of analog-to-digital conversion according to the described examples.

The same reference numbers or other reference designators are used in the drawings to illustrate the same or similar (in function and/or structure) features.

### DETAILED DESCRIPTION

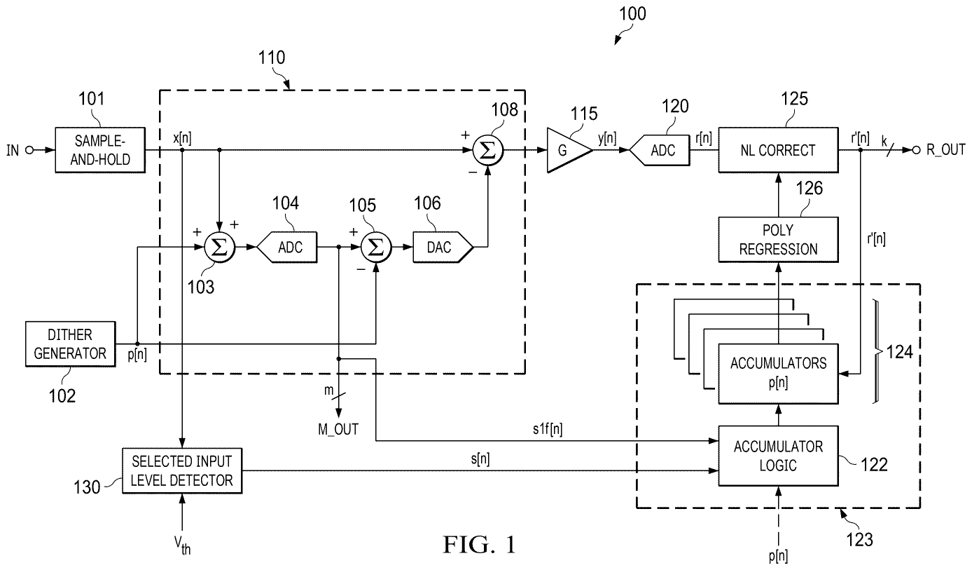

FIG. 1 illustrates analog-to-digital converter (ADC) 100 according to an example. ADC 100 includes sample-and-hold circuit 101, dither generator 102, first ADC stage 110, residue amplifier 115, second ADC stage 120, non-linearity correction circuit 125, selected input level detector circuit 130, accumulator circuitry 123, and polynomial regression logic 126. First ADC stage 110 includes adders 103, 105, and 108, ADC circuit 104, and digital-to-analog converter (DAC) circuit 106. Accumulator circuitry 123 includes accumulator logic 122 and accumulators 124.

Sample-and-hold circuit 101 has an input IN, for example receiving a continuous-time analog signal. For example, sample-and-hold circuit 101 may include a switch (e.g., a transistor pass gate) and a capacitor. The switch may be controlled by a sample clock signal (e.g., generated by a clock circuit, not shown) to periodically couple the capacitor to input IN, acquiring a sample x[n] of the continuous-time analog signal. A stream of samples x[n] of the signal at input IN is provided by sample-and-hold circuit 101 at a sample rate determined by the sample clock signal. Sample-and-hold circuit 101 may be included within the same integrated circuit as ADC 100, or alternatively may be implemented in a separate integrated circuit (e.g., an analog “front end”, or AFE, circuit).

The output of sample-and-hold circuit 101 is coupled to an input of first ADC stage 110, specifically to an input of each of adder 103 and adder 108. In this example, adder 103 has a second input coupled to an output of dither generator 102. Adder 103 in this example is implemented as an analog adder circuit, one example of which is a summing amplifier. Dither generator 102 generates a dither signal p[n], for example as a sequence of analog levels of random amplitude appearing at the sample rate of sample stream x[n]. For example, dither generator 102 may be implemented as a logic circuit generating multi-bit digital words in a pseudo-random binary sequence (PRBS), with a digital-to-analog converter (DAC) presenting an analog level corresponding to each of the PRBS words. Adder 103 has an output coupled to an input of ADC circuit 104.

In this example, adder 103 adds the dither signal p[n] to the input sample stream x[n], effectively adding wide-band noise to the input signal. The effect of the wide-band noise from dither signal p[n] in the summed signal is to spread coherent signal spurs (e.g., due to differential non-linearity, or DNL) into the noise floor, thus improving the signal to noise ratio (SNR).

ADC circuit 104 in this example digitizes the summed signal at the output of adder 103 to produce an m-bit digital representation of that summed signal. The number m of bits generated by ADC circuit 104 may range from one to several bits. In this example of pipelined ADC 100, however, the number m of bits from ADC circuit 104 constitutes the m most significant bits (MSBs) of the eventual digital output word, with one or more later stages (e.g., second ADC stage 120) generating one or more least significant bits (LSBs). The m MSBs generated by ADC circuit 104 appear at output M_OUT of ADC 100 for each input sample x[n].

ADC circuit 104 may be implemented as any one of a number of ADC circuit types. In this example, ADC circuit 104 is implemented as a “flash” or direct-conversion ADC, including for example a number of comparators having different threshold levels set by a resistive or capacitive voltage ladder. Other types of ADC circuits may alternatively be used as ADC circuit 104, such types including successive-approximation-register (SAR) ADCs, delta-sigma ADCs, sigma-delta modulator ADCs, and the like.

The output of ADC circuit 104 is coupled to an input of adder 105. Another input of adder 105 is coupled to the output of dither generator 102 to receive dither signal p[n]. Adder 105 in this example subtracts the dither signal sample p[n] (that added at adder 103) from the output of ADC circuit 104, and presents the difference to an input of DAC circuit 106. This subtraction by adder 105 removes the wide-band noise added by dither signal p[n] from the output of ADC circuit 104, avoiding SNR degradation of first ADC stage 110 due to the added wide-band noise.

DAC circuit 106 may be implemented in any one of a number of DAC circuit types, for example as a summing amplifier with weighted input resistors, a summing amplifier with an input resistor ladder, and the like. The output of DAC circuit 106 is coupled to an input of adder 108, which receives the input sample x[n] at another input as mentioned above. Adder 108 is implemented to subtract the analog signal at the output of DAC circuit 106 from the analog input sample x[n]. The output of adder 108 is coupled to an input of residue amplifier 115. The difference generated by adder 108 constitutes the residue from first ADC stage 110.

Residue amplifier 115 has an output presenting an amplified residue signal y[n] in response to the residue from first ADC stage 110. The output of residue amplifier 115 is coupled to an input of second ADC stage 120. Second ADC stage 120 may be implemented with a similar architecture as first ADC stage 110, or with a different type of ADC circuitry, to generate a digital output signal r[n] corresponding to a digitization of the amplified residue signal y[n] from residue amplifier 115. The output of second ADC stage 120 is coupled to an input of correction circuit 125. Correction circuit 125 applies a correction to remove non-linearities in the digitized residue signal r[n]. In this example, correction circuit 125 generates a k-bit digital value, corresponding to a corrected residue signal r′[n], at output R_OUT of ADC 100. In this two-stage implementation of ADC 100, the k-bit result at output R_OUT constitutes the k LSBs of the digital value generated by ADC 100 from analog input sample x[n]. Concatenation of the MSBs at output M_OUT and the LSBs at output R_OUT provides the full digital output word generated by ADC 100 for the analog input sample x[n].

In general, the residue signal generated by adder 108 of first ADC stage 110 is a difference between two approximately equal analog signals, namely the input sample x[n] and that input sample x[n] after digitization by ADC circuit 104 and conversion back to analog by DAC circuit 106. As a result, this residue signal generally has a low amplitude and may thus be vulnerable to noise. To address this noise vulnerability, residue amplifier 115 amplifies the residue signal from first ADC stage 110 to provide a residue signal with a higher amplitude to second ADC stage 120, reducing the effect of circuit noise on that residue signal. Higher gain values in this amplification can reduce the impact of noise but result in large voltage swings at the output of residue amplifier 115.

It is of course desirable to reduce the chip area and power consumption of residue amplifier 115, for example by implementing ADC 100 using the extremely small transistor sizes of advanced manufacturing process nodes. However, these smaller devices often require reduced power supply voltages (e.g., 1.2V), in contrast to the higher power supply voltages (e.g., 3 V) used with less aggressive transistor sizes. At such reduced power supply voltages, the large output voltage swing resulting from high gain at residue amplifier 115 can exhibit significant non-linearity in the amplified residue signal, leading to degradation in SNR and SFDR if not properly corrected downstream in ADC 100.

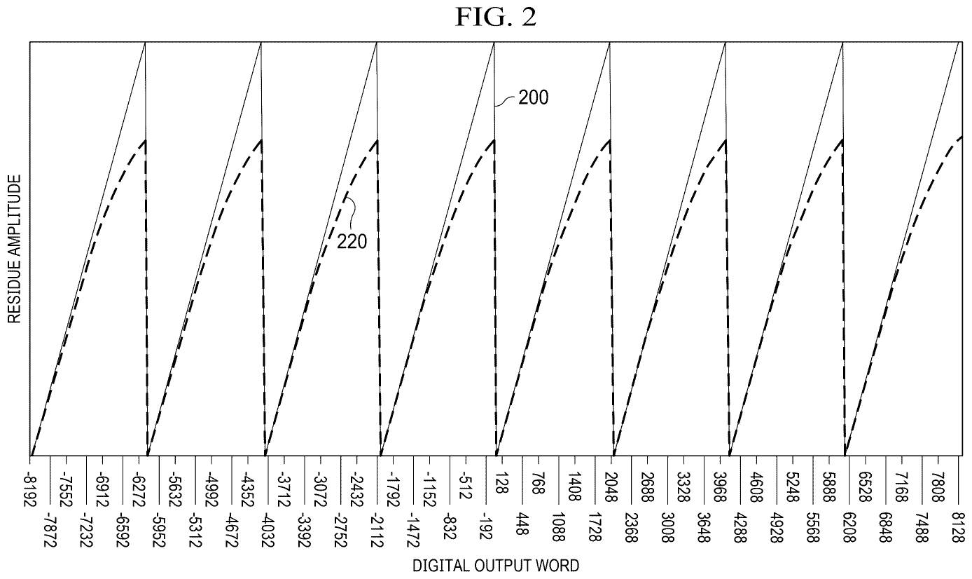

FIG. 2 illustrates an example of non-linearity in the amplified residue signal produced by residue amplifier 115. Plot 200 in FIG. 2 illustrates the ideal residue amplitude between digital levels over the full range of the digital output from ADC 100 (e.g., ranging from −8192 to +8128), for the case in which first ADC stage 110 generates three digital bits (m=3). As shown in FIG. 2, the ideal residue amplitude increases linearly between each of the eight digital thresholds. However, non-linearities resulting from residue amplifier 115 result in distortion of residue amplitude from the ideal, as shown by plot 220. In this example, these non-linearities cause a flattening of the slope of residue amplitude between digital thresholds. Significant error is thus present in the amplified signal representing larger residue values within each digital level.

According to the examples described below, correction circuit 125 operates to correct for non-linearities in the digitized residue signal r[n], such as resulting from the gain applied by residue amplifier 115 to the residue from first ADC stage 110. More particularly, correction circuit 125 additively (e.g., adds or subtracts, as the case may be) corrects residue signal r[n] according to a polynomial estimate of the non-linear residue characteristic (e.g., as shown by plot 220), restoring a linear characteristic to corrected residue r′[n]. According to these examples, this polynomial estimate is based on the response of ADC 100 at multiple levels of a signal added to input samples at a selected input level. For example, the known added signal levels may be levels of a dither signal p[n] generated by dither generator 102. Alternatively, a separate signal at known signal levels may be added to the input samples x[n] at a known level (e.g., 0V). In either case, the added signal (e.g., dither signal p[n]) is used to establish multiple regression points from which a polynomial estimate of the non-linear response of residue amplifier 115 can be generated.

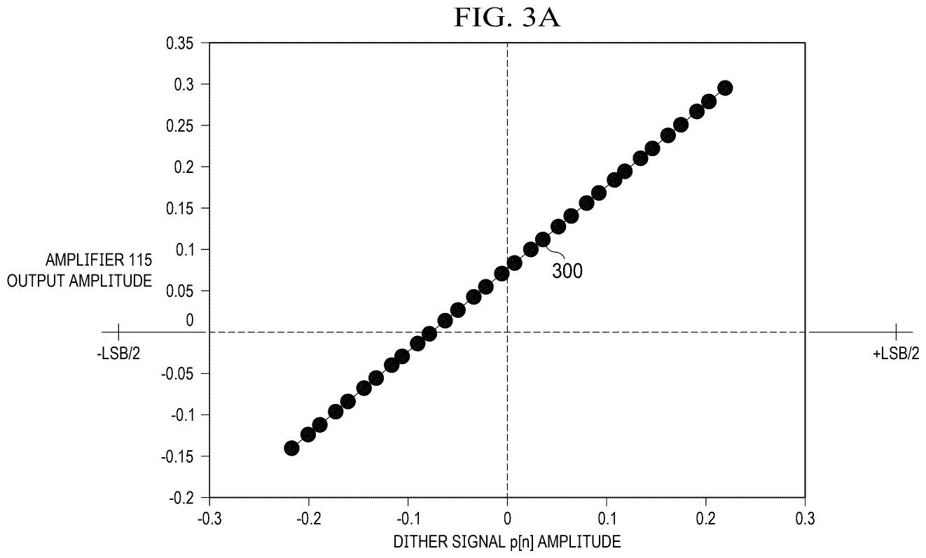

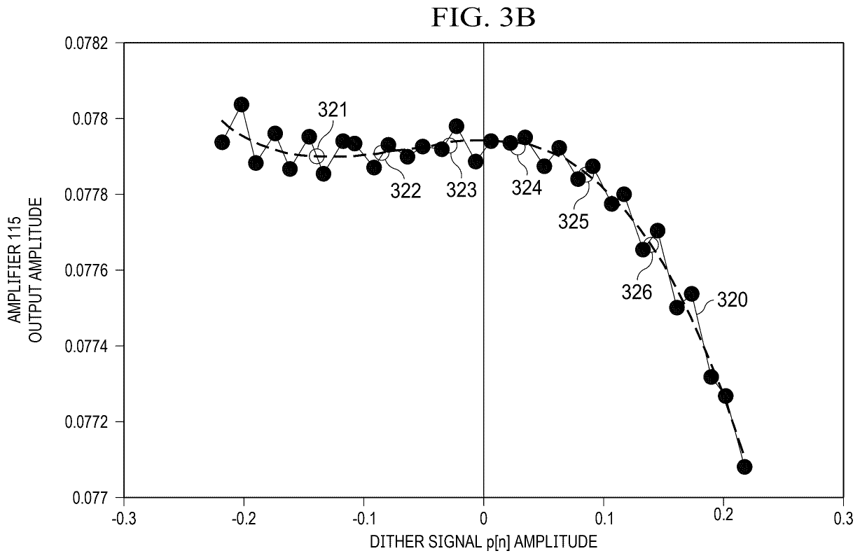

FIGS. 3A and 3B illustrate examples of the amplitude of the amplified residue signal y[n] from residue amplifier 115 in response to varying amplitudes of an added signal at known signal levels, for example dither signal p[n], for linear and higher-order cases, respectively. In this example, dither generator 102 generates dither signal p[n] based on a five-bit PRBS value, and thus at one of thirty-two different amplitudes. In the example of FIGS. 3A and 3B, the input sample x[n] is assumed to be nominally 0V, such that the residue signal y[n] has amplitudes extending both above and below this nominal level. In this example, the maximum analog amplitude (both positive and negative) of dither signal p[n] is well below the digitization thresholds (e.g., ±LSB/2) of ADC circuit 104, and thus provide the same digital output result as the nominal amplitude of the input sample (e.g., 0V).

In the example of FIGS. 3A and 3B, a polynomial estimate of the amplitude of the residue signal y[n] at the output of residue amplifier 115 is:

$$y = - 0.043 {x}^{3} - 0.0083 {x}^{2} + 0.9996 x + 0.0779 . \qquad [ 1 ]$$

Plot 300 of FIG. 3A plots the amplitude of linear and constant components of the polynomial estimate of equation [1]:

$${y}_{l i n} = 0.9996 x + 0 \text{.0779} \qquad [ 2 a ]$$

while plot 320 of FIG. 3B illustrates the higher-order and constant terms of this estimate:

$${y}_{h} = - 0.043 {x}^{3} - 0.0083 {x}^{2} + 0.0 779. \qquad [ 2 b ]$$

In this example, the estimate of equation [1] is derived from a third-order polynomial regression, using the six regression points 321, 322, 323, 324, 325, 326 shown in FIG. 3B.

In ADC 100 of FIG. 1, accordingly, correction for non-linearities at the output of second ADC stage 120 can be thought of as adjusting residue signal r[n] to negate the higher-order and constant terms of the polynomial estimate, for example by subtracting the result yₕ of equation [2b] for the current amplitude of the residue signal r[n]. The corrected residue signal r′[n] more closely follows the linear characteristic of equation [2a] as a result.

In order to derive a polynomial estimate, however, one must measure the residue signal for known input sample amplitudes at a sufficient number of regression points (e.g., points 321 through 326 of FIG. 3B). According to these examples, these multiple regression points are obtained at input sample amplitudes corresponding to input signal x[n] at a known level (e.g., 0V) plus an added signal at a known level. Multiple levels of the added signal define the multiple regression points. This added signal may be a signal dedicated to the purpose of defining regression points, or any other signal added to input signal x[n] at the known level. ADC 100 according to these examples advantageously utilizes dither signal p[n] as generated by dither generator 102 as this added signal, thus obtaining the improved SNR provided by dithering of the input signal in addition to providing regression points for polynomial regression of the transfer function of residue amplifier 115.

In example ADC 100 of FIG. 1, the residue signal at the input of residue amplifier 115 can be considered as the sum of input sample x[n], analog dither p[n], and the output from DAC circuit 106. For the case of input sample x[n] with a zero nominal amplitude, the digital output of ADC circuit 104 is also zero. Ideally in this case, a zero level input to DAC circuit 106 is at its mid-range point, such that the nominal output of DAC circuit 106 is also zero (with minimal offset at this mid-range point). Under these zero-level conditions, the input to residue amplifier 115 corresponds to the current analog amplitude of dither signal p[n], which is determined by the pseudo-random binary sequence from dither generator 102.

According to these examples, a higher-order (e.g., third order) polynomial estimate for use in correcting non-linearities is derived during normal operation of ADC 100, by performing a regression of the residue signal at known input levels. More particularly, the known input levels are the known amplitudes of dither signal p[n] added to a known (e.g., selected) amplitude of input sample x[n], for example a zero input level. In this example, ADC 100 includes circuitry for detecting input samples x[n] having a known value (e.g., zero amplitude), estimating a polynomial for the non-linearity characteristic of residue amplifier 115 at varying input levels corresponding to amplitudes of dither signal p[n], and applying a correction at the ADC output to compensate for these residue amplifier non-linearities. This circuitry includes selected input level detector 130, accumulator logic 122 and accumulators 124, polynomial regression logic 126, and correction circuit 125.

Referring to FIG. 1, selected input level detector 130 has an input coupled to the output of sample-and-hold circuit 101, to receive analog input samples x[n]. Selected input level detector 130 also has an input receiving a threshold voltage Vₜₕ, for example at a common potential (e.g., Vₜₕ=0V, or circuit ground), or at a selected reference voltage generated by a voltage reference circuit (not shown) or the like. Selected input level detector 130 has an output coupled to an input of accumulator logic 122. In this example, selected input level detector 130 produces a signal s[n] indicating that an input signal sample x[n] has a value at that corresponding to threshold voltage Vₜₕ (e.g., the “selected input level”).

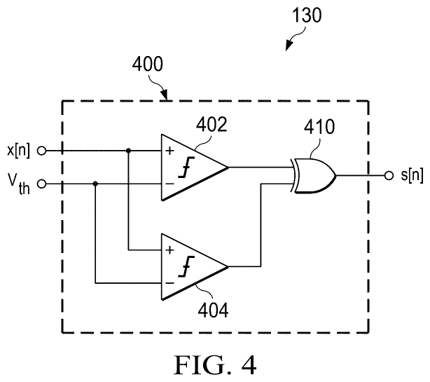

FIG. 4 illustrates an example of selected input level detector 130. In this example, selected input level detector 130 is stochastic comparator 400. Stochastic comparator 400 includes comparators 402 and 404, and logic gate 410.

Each of comparators 402 and 404 in stochastic comparator 400 according to this example has a positive input coupled to the output of sample-and-hold circuit 101, and a negative input receiving the threshold voltage Vₜₕ. For the example of a selected input level at the midpoint of the range of ADC 100 (e.g., 0V), threshold voltage Vₜₕ is at 0V (e.g., the negative inputs of comparators 402 and 404 are coupled to circuit ground). The outputs of comparators 402 and 404 are coupled to inputs of logic gate 210, which in this example is an exclusive-OR gate 410. The output of exclusive-OR gate 410 presents signal s[n] to accumulator logic 122.

In operation, because comparators 402 and 404 receive the same inputs as one another, comparators 402 and 404 provide the same output logic state, subject to the effects of random noise. Conversely, if comparators 402 and 404 generate opposite output states, as indicated by a “1” state at the output of exclusive-OR gate 410 (e.g., signal s[n]=1), one can conclude that the analog level of input sample x[n] is at threshold voltage Vₜₕ, differing only by an amount within the noise floor of ADC 100 plus any noise at comparators 402 and 404 themselves. For example, if the random noise in ADC 100 is expressed by a standard deviation 6=5 mV, one can conclude (assuming ideal comparators 402, 404) that 95% of the input samples x[n] for which stochastic comparator 400 generates an output signal s[n]=1 are within ±10 mV of the selected input level corresponding to threshold voltage Vₜₕ (e.g., 0V). Accordingly, selected input level detector 130, in the form of stochastic comparator 400 in this example, issues signal s[n]=1 in response to each input sample x[n] that is at a selected input level, such as 0V in one example.

Referring back to FIG. 1, accumulator logic 122 also has an input coupled to the output of ADC circuit 104, to receive a signal s1f[n] indicating the value at output M_OUT. Accumulator logic 122 may also have an input coupled to the output of dither generator 102, to receive dither signal p[n]. Accumulator logic 122 has one or more outputs coupled to accumulators 124.

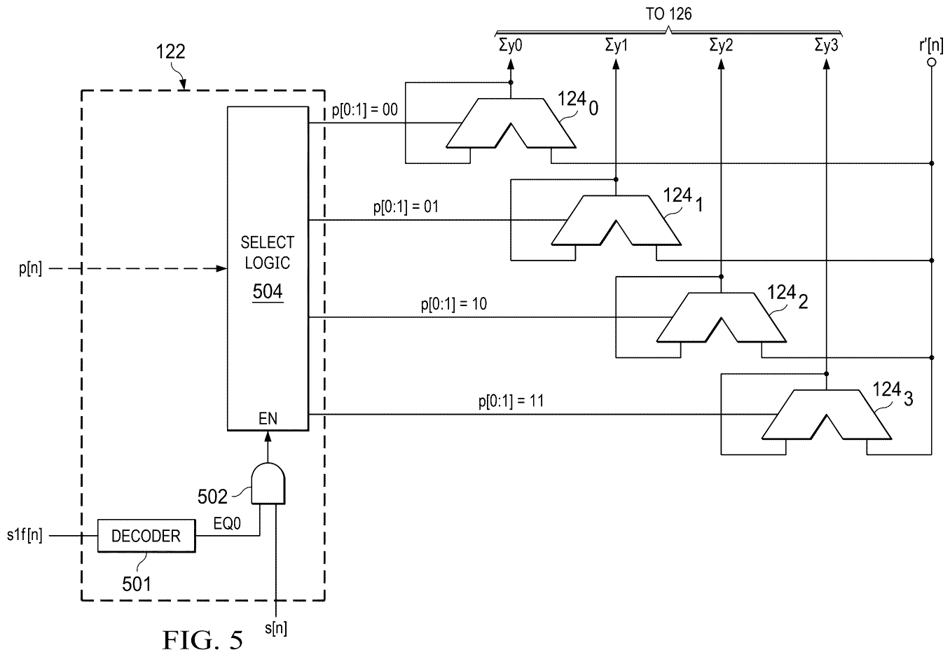

FIG. 5 illustrates an example functional architecture of accumulator logic 122 in combination with accumulators 124. Accumulator logic 122 in this example architecture includes decoder 501, logic gate 502, and select logic 504. Accumulators 124 include accumulator 124₀, accumulator 124₁, accumulator 124₂, and accumulator 124₃.

The architecture of accumulator logic 122 shown in FIG. 5 is presented to illustrate its functionality in ADC 100 according to this example. In practice, accumulator logic 122 may be implemented in any of a number of various logic circuit arrangements, including combinational logic, sequential logic, and programmable logic executing a sequence of program instructions stored in a memory resource. Accumulators 124 may be implemented as registers or memory locations storing accumulated sums, for example according to program instructions executed by programmable logic, or alternatively as hardware accumulators (e.g., adders).

In this example architecture of FIG. 5, decoder 501 of accumulator logic 122 has an input coupled to the output of ADC circuit 104 to receive signal s1f[n]. Signal s1f[n] corresponds to the digital output of ADC circuit 104 in response to input sample x[n] (as dithered by dither signal p[n]). Signal s1f[n] may consist of the m MSBs provided by ADC circuit 104, or may correspond to fewer than all of the m bits (e.g., one or more MSBs of the m bit output). Decoder 501 has an output coupled to one input of logic gate 502, presenting signal EQ0. Logic gate 502, which is an AND gate in this example, has a second input coupled to the output of selected input level detector 130, to receive signal s[n]. Logic gate 502 has an output coupled to an enable input EN of select logic 504. Select logic 504 may have an input coupled to the output of dither generator 102 to receive dither signal p[n]. Alternatively, select logic 504 may include PRBS logic, a memory, or other circuitry indicating the current value of dither signal p[n] for the current input sample x[n].

Select logic 504 of accumulator logic 122 has an output coupled to an enable input of each of accumulators 124₀, 124₁, 124₂, and 124₃. Each of accumulators 124₀, 124₁, 124₂, and 124₃ has an input coupled to the output of correction circuitry 125 (FIG. 1) to receive corrected residue signal r′[n], an output coupled to polynomial regression logic 126, and a second input coupled to its output. Accumulators 124₀, 124₁, 124₂, and 124₃ each add the current value of corrected residue signal r′[n] to its contents when enabled by a signal from selected logic 122. Accumulators 124₀, 124₁, 124₂, and 124₃ present signals Σy0, Σy1, Σy2, Σy3, respectively, to polynomial regression logic 126. Each of signals Σy0, Σy1, Σy2, Σy3 indicates the current contents of its corresponding accumulator 124₀, 124₁, 124₂, 124₃, respectively.

The number of accumulators 124 implemented in ADC 100 corresponds to the number of points used to derive a polynomial non-linearity estimate. In this example, the four accumulators 124₀, 124₁, 124₂, and 124₃ shown in FIG. 5 establish four points, which is the minimum number for estimating a third-order polynomial. More than the minimum number of accumulators 124 are provided in other examples. For example, the use of six accumulators 124 (e.g., corresponding to the six points 321 through 326 of FIG. 3B) can provide a more accurate estimate of a third-order polynomial. Accordingly, the number of accumulators 124 can vary from the described example.

In operation, AND gate 502 receives signal s[n] from selected input level detector 130. Signal s[n] indicates, with a “1” logic level in this example, that the current input sample x[n] is at an analog level at threshold Vₜₕ, which is 0V (e.g., circuit ground) in this example. A “0” logic level of signal s[n] indicates that the current input sample s[n] is at an analog level other than 0V.

At the same time, decoder 501 receives signal s1f[n] from ADC circuit 104. Signal s1f[n] in this example architecture is a digital value corresponding to up to m bits of the digital output of ADC circuit 104 at output M_OUT. Decoder 501 determines whether the digital value of signal s1f[n] matches the selected input level corresponding to threshold Vₜₕ, and to issue signal EQ0 indicating the result. In this example in which threshold Vₜₕ=0V, decoder 501 presents signal EQ0 at a “1” logic level in response to signal s1f[n] having the matching digital value (e.g., “00”), and at a ‘0’ logic level otherwise. Signal EQ0 is received at a second input of AND gate 502.

In general, the evaluation of digital signal s1f[n] by decoder 501 is optional. This evaluation is provided in this example to eliminate spurious results from the polynomial estimation and correction, however. For example, a noise event can cause the digitization by ADC circuit 104 of input sample x[n], as dithered, to provide an incorrect (e.g., non-zero) result. Confirmation of the correct digital result, by this evaluation of signal s1f[n], ensures that these results are not considered in the polynomial estimation.

In response to both signal s[n] and signal EQ0 at a “1” logic level, which in this example corresponds to input sample x[n] being at 0V in combination with the corresponding digital output from ADC circuit 104 at a digital zero value, AND gate 502 presents a “1” logic level to the enable input of select logic 504. Select logic 504 selects the one of accumulators 124₀, 124₁, 124₂, 124₃ to be enabled in that event, based on the current known level of an added signal. In this example in which the added signal is dither signal p[n], the known level of the added signal is the current value of dither signal p[n].

Select logic 504 may include a decoder or other logic to issue an enable signal to one of accumulators 124₀, 124₁, 124₂, 124₃. For example, select logic 504 may have an input coupled to an output of dither generator 102, to receive dither signal p[n](e.g., a digital value corresponding to the dither signal p[n] applied to adder 103). Alternatively, select logic 504 may include PRBS logic, or memory, or the like for determining the digital value of dither signal p[n] in each sample period.

The number of accumulators 124 may be fewer than the number of available dither levels of dither signal p[n]. For example, a five-bit dither signal p[n] may take any one of thirty-two analog levels, while fewer accumulators 124 (e.g., four, six, etc.) are provided. Accordingly, the selection of one of accumulators 124 may be based on two or more MSBs of the digital value of dither signal p[n], as shown in FIG. 5. Alternatively, this selection may be made by an analog comparator in select logic 504 comparing the analog value of dither signal p[n] with four or more threshold levels. In the example of FIG. 5, select logic 504 evaluates the two MSBs (e.g., bit positions 0 and 1) of the digital value of dither signal p[n]. As such, select logic 504 selects accumulator 124₀ responsive to MSBs p[0:1]=00, selects accumulator 124₁ responsive to MSBs p[0:1]=01, selects accumulator 124₂ responsive to MSBs p[0:1]=10, and selects accumulator 124₃ responsive to MSBs p[0:1]=11.

In this example, the one of accumulators 124 that is selected by select logic 504 in response to selected input level detector 130 detecting an input sample x[n] at the threshold level (e.g., 0V) operates to add the current value of corrected residue signal r′[n] at the output of correction circuit 125 to its current accumulated contents. For example, if accumulator 124₀ is enabled by select logic 504, the current value of corrected residue signal r′[n] is added to the sum Σy0 at the output of accumulator 124₀ (or, as stored in accumulator 124₀), and the sum Σy0 updated accordingly.

Over time, each of accumulators 124 can accumulate the results for a number of input samples x[n] at the threshold level (e.g., 0V), as dithered by dither signal p[n] at a value associated with selection of that accumulator. With a sufficient number of those samples, the sums Σy0, Σy0, Σy0, Σy3 at the output of accumulators 124₀, 124₁, 124₂, 124₃, and forwarded to polynomial regression logic 126, can provide a reasonable basis for estimating a polynomial expression for the response of residue amplifier 115. A criterion for determining whether a sufficient number of samples have been obtained may be a minimum number of samples per accumulator 124, or a preselected error criterion applied to the LMS minimization, or the like.

Polynomial regression logic 126 may be implemented by way of programmable logic, for example to execute program instructions stored in a memory, or as another form of digital logic circuitry. For the example of programmable logic, such as a microprocessor or other data processing circuit, the executable program instructions may correspond to an algorithm for estimating the coefficients of a polynomial of selected order (e.g., third-order), for example according to a least-mean-squares (LMS) optimization using matrix inversion.

According to this example, polynomial regression logic 126 estimates a third-order polynomial y for amplified residue signal y[n] (e.g., at the output of residue amplifier 115):

$$y = {α}_{3} {x}^{3} + {α}_{2} {x}^{2} + {α}_{1} x + β \qquad [ 3 ]$$

More particularly, polynomial regression logic 126 performs this estimation by performing an LMS minimization of an error e(x):

$$e ( x ) = {[ y - ( {α}_{3} {x}^{3} + {α}_{2} {x}^{2} + {α}_{1} x + β ) ]}^{2} \qquad [ 4 ]$$

across each of the coefficients α₃, α₂, α₁, and β, at each of the regression points represented by the sums Σy0, Σy0, Σy0, Σy3 at the output of accumulators 124₀, 124₁, 124₂, 124₃ (e.g., an arithmetic mean of the residue values r′[n] accumulated at each accumulator 124₀, 124₁, 124₂, 124₃ over the number of dither values for that accumulator). In one example, this LMS minimization is executed by polynomial regression logic 126 performing a differentiation of the error expression e(x) of equation [4], with respect to each of the coefficients α₃, α₂, α₁, and β, arriving at a system of four equations:

$$\sum y {x}^{3} = {α}_{3} \sum {x}^{6} + {α}_{2} \sum {x}^{5} + {α}_{1} \sum {x}^{4} + β \sum {x}^{3} \qquad [ 5 a ]$$

$$\sum y {x}^{2} = {α}_{3} \sum {x}^{5} + {α}_{2} \sum {x}^{4} + {α}_{1} \sum {x}^{3} + β \sum {x}^{2} \qquad [ 5 b ]$$

$$\sum y {x}^{1} = {α}_{3} \sum {x}^{4} + {α}_{2} \sum {x}^{3} + {α}_{1} \sum {x}^{2} + β \sum {x}^{1} \qquad [ 5 c ]$$

$$\sum y = {α}_{3} \sum {x}^{3} + {α}_{2} \sum {x}^{2} + {α}_{1} \sum {x}^{1} + β \sum {x}^{0} \qquad [ 5 d ]$$

This system of the four equations [5a], [5b], [5c], [5d] with four unknowns (e.g., the coefficients as, α₂, α₁, and β) can be solved by numerical techniques, such as matrix inversion, in polynomial regression logic 126.

Correction circuit 125 receives the result of the estimate performed by polynomial regression logic 126, and derives a correction to be applied to the residue signal r[n] from second ADC stage 120. For example, correction circuit 125 derives a subtraction c[n]:

$$c [ n ] = {\hat{α}}_{3} {r [ n ]}^{3} + {\hat{α}}_{2} {r [ n ]}^{2} \qquad [ 6 ]$$

where the coefficients \hat{α}₃, \hat{α}₂ are the coefficients estimated by polynomial regression logic 126 for the higher-order (e.g., higher than linear) terms of the response of residue amplifier 115. In this case, correction circuit 125 generates corrected residue signal r′[n] by subtracting the correction c[n] from residue signal r[n] at the output of second ADC stage 120, which effectively corrects for the higher-order non-linearities in the amplified residue signal y[n] at the output of residue amplifier 115.

In this example, accumulators 124 continue to accumulate additional instances of corrected residue signal r′[n] corresponding to input samples x[n] at the threshold level Vₜₕ (e.g., 0V) as detected by selected input level detector 130, and thus corresponding to the dither signal p[n] levels associated with the individual accumulators 124₀, 124₁, 124₂, 124₃. In this manner, polynomial regression logic 126 updates the polynomial estimates as additional data are accumulated, and as the correction c[n] applied by correction circuit 125 improves the linearity of corrected residue signal r′[n].

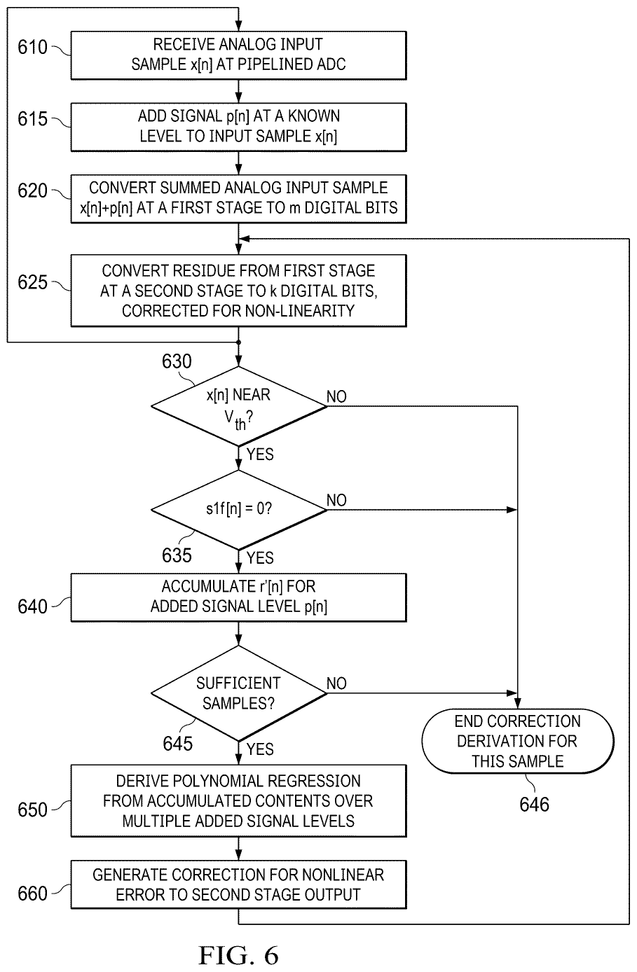

FIG. 6 is a flow diagram of an example method of operating ADC 100 according to the examples described above. In this example method of FIG. 6, polynomial regression is performed at multiple regression points that each correspond to an input sample x[n] at a known level (e.g., 0V) plus an added signal p[n] at a known level. For example, as described above, this added signal is the dither signal p[n]. The following description of this example method refers to the particular elements of ADC 100 as shown in FIG. 1 and described above, by way of example.

This example method of FIG. 6 is applied to each input sample x[n], for example by sample-and-hold circuit 101 in response to a received analog signal. In process block 610, pipelined ADC 100 receives an instance of input sample x[n], from sample-and-hold circuit 101 or otherwise, in the form of an analog level, such as a voltage.

In process block 615, a signal p[n] at a known signal level (for example, the dither signal p[n] generated by dither generator 102) is added to input sample x[n] (e.g., at adder 103), and this summed input sample (e.g., x[n]+p[n]) is converted by first ADC stage 110 to a digital value expressed by m bits (m≥1). A residue signal from first ADC stage 110, for example as generated by the digital-to-analog conversion of the m bit output (e.g., by DAC circuit 106) and subtracted from input sample x[n] (e.g., at adder 108), is then forwarded to second ADC stage 120, after amplification by residue amplifier 115 in the example of FIG. 1. In process block 625, this residue (as amplified by residue amplifier 115) is converted to a digital value expressed by k bits (k≥1).

Process block 625 in this example includes a correction of the output of second ADC stage 120 to remove non-linearities such as caused by residue amplifier 115. According to the example described above, this correction is based on a polynomial regression of the response of ADC 100 to selected dithered input samples x[n]+p[n], where the input sample x[n] is at a selected input level (e.g., 0V). The correction applied in process block 625 is an additive (or subtractive) correction for one or more non-linear (e.g., higher-order) terms in the estimated polynomial. The example method of FIG. 6 includes the derivation of the correction applied in process block 625.

Decision 630 determines whether the current input sample x[n] is at a threshold level, for example 0V. As described above relative to FIG. 4, decision 630 may be performed by stochastic comparator 400, which includes two comparators 402, 404 that both have one input receiving input sample x[n] and another input receiving a threshold voltage Vₜₕ (e.g., at circuit ground, or 0V). The outputs of comparators 402, 404 are coupled to inputs of exclusive-OR gate 410. Exclusive-OR gate 410 issues a positive (“yes”) result for decision 630 (e.g., a logic “1” level) in response to the outputs of comparators 402, 404 differing from one another. This condition can occur with input sample x[n] being at a level within the noise floor of threshold level Vₜₕ, such that noise at comparators 402, 404 produces different output results. Conversely, decision 630 returns a “no” result in response to input sample x[n] being at a level that is not near threshold level Vₜₕ, for which comparators 402, 404 have the same result as one another. In response to a “no” result for decision 630, the current input sample x[n] is not used in the derivation (or update) of the correction of process block 625 (state 646 of FIG. 6).

If decision 630 is a “yes”, decision 635 evaluates whether first ADC stage 110 presents, at its output, a digital value consistent with the threshold level Vₜₕ. For example, decision 635 is performed to ensure that a large noise event did not erroneously cause differing output results at comparators 402, 404 of stochastic comparator 400. Decision 635 is an optional process, as it serves to confirm positive results from decision 630. If decision 635 returns a “no” result, the current input sample x[n] is not used in the derivation (or update) of the correction of process block 625 (state 646 of FIG. 6).

Decisions 630, 635 may be executed simultaneously, in either order, or asynchronously, relative to one another. In response to both of decisions 630 and 635 returning a “yes” result, process block 640 is performed. In process block 640, the one of accumulators 124 corresponding to the current level of the added signal p[n] for input sample x[n] adds the current corrected output from second ADC stage 120 (e.g., the corrected residue signal r′[n] at the output of correction circuit 125 in FIG. 1) to its previously stored contents. This accumulator 124 may be identified from the values of two or more MSBs of the current dither level p[n], or may correspond to a range of dither levels, as described above.

Decision 645 determines whether a sufficient number of input samples x[n] at the threshold level Vₜₕ have been acquired, at each of the regression points (e.g., at each of accumulators 124), to obtain a good polynomial regression. The criterion for decision 645 may be a selected count of samples at each accumulator 124 or the like. If not (decision 645 is “no”), the current input sample x[n] is not used in the derivation (or update) of the correction of process block 625 (state 646 of FIG. 6).

If a sufficient number of input samples x[n] have been accumulated at accumulators 124 (decision 645 is “yes”), process block 650 is performed to derive a polynomial regression from the contents of accumulators 124 as obtained at various levels of the added signal (e.g., at various dither levels) in process block 640. In this example, process block 640 includes a LMS minimization of an error e(x), for example as expressed in equation [4] for a third-order polynomial regression. As described above, this LMS minimization may be executed by polynomial regression logic performing a matrix inversion of a system of equations derived from differentiation of the third-order polynomial error e(x) with respect to each of the four polynomial coefficients. Other approaches for estimating a polynomial expression for non-linear amplified residue signal are also contemplated.

In process block 660, a correction for the nonlinear error to be applied in process block 625 is generated. For the example of an estimate of a third-order polynomial based on a regression in process block 650, this correction includes the non-linear terms of the estimated polynomial, such as described above relative to equation [6]. This correction may be made in process block 625 by correction circuitry 125 subtracting the result of equation [6] for the current value of input sample x[n] from the output of second ADC stage 120.

The method of FIG. 6 according to this example is then repeated for each input sample x[n] instance converted by ADC 100, with any additional input sample values at the threshold level Vₜₕ used to update the polynomial regression and correction during the operation of ADC 100.

As noted above, decision 645 determines whether a sufficient number of input samples x[n] at the selected threshold level Vₜₕ have been obtained, in order to generate an accurate polynomial regression and correction. In some instances, however, the nature of the input signal to ADC 100 does not result in a sufficient number of such input samples during normal operation. For example, if the input signal to ADC 100 has the form of a square wave at positive and negative amplitudes, very few samples will be obtained at a 0V threshold level. In such a case, logic circuitry in ADC 100 may monitor the result of decision 645, and modify the selected input level, for example by changing the threshold voltage Vₜₕ applied to stochastic comparator 400. Operation of ADC 100 in carrying out the example method of FIG. 6 can then be executed at this different threshold level.

The described examples illustrate correction of the residue signal r[n] at the output of second ADC stage 120. According to example pipelined ADCs in which more than two ADC stages are implemented, similar correction of the residue signal may be additionally determined and applied to the residue signal at the output of a third and/or later ADC stages. Further in the alternative, for such pipelined ADCs having more than two ADC stages, the determination and correction of a later stage residue signal may be applied at one or more but not all of the ADC stages (e.g., with the correction determined for and applied at the output of a third ADC stage in the pipeline but not the second ADC stage). These and other alternative implementations are contemplated in connection with the described examples.

According to the described examples, a pipelined ADC is provided that can attain significant reduction in integral non-linearity (INL) in modern ADC devices, for example as manufactured at advanced process nodes. In particular, these examples enable high gain at the residue amplifier at the output of a first ADC stage in the pipeline, even at low power supply voltages (e.g., 1.2V), while also maintaining low power consumption by the device. Costly alternatives such as parallel signal paths for calibration, and device trimming by automated test equipment at the time of manufacture, can be avoided.

Examples are described in this specification as implemented into an analog-to-digital converter integrated circuit as such implementation can be advantageous in that context. However, aspects of these examples may be beneficially applied in alternative applications, for example as ADCs embedded into digital receivers and other larger scale implementations. Accordingly, the above description is provided by way of example only, and is not intended to limit the true scope as claimed.

As used herein, the terms “terminal”, “node”, “interconnection” and “pin” are used interchangeably. Unless specifically stated to the contrary, these terms are generally used to mean an interconnection between or a terminus of a device element, a circuit element, an integrated circuit, a device, or other electronics or semiconductor component.

Unless otherwise stated, “about,” “approximately,” or “substantially” preceding a value means +/−10 percent of the stated value. Modifications are possible in the described examples, and other examples are possible within the scope of the claims.

A device that is “capable of” performing a task or function may be configured (e.g., programmed and/or hardwired), for example at a time of manufacturing by a manufacturer, to perform the function and/or may be configurable (or reconfigurable), for example by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. While, in some example embodiments, certain elements are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

Modifications are possible in the described examples, and other examples are possible, within the scope of the claims.

What is claimed is:

1. An analog-to-digital converter (ADC), comprising:
a first ADC stage, having a first input, a second input, a digital output, and a residue output;
a signal generator circuit, having an output coupled to the second input of the first ADC stage;
a selected input level detector, having an input coupled to the first input of the first ADC stage, and having an output;
a residue amplifier, having an input coupled to the residue output of the first ADC stage, and having an output;
a second ADC stage, having an input coupled to the output of the residue amplifier, and having an output;
a correction circuit, having a first input coupled to the output of the second ADC stage, and having a second input and an output;
accumulator circuitry, having an input coupled to the output of the selected input level detector, and having an output, the accumulator circuitry comprising a plurality of accumulators, each accumulator having an input coupled to the output of the correction circuit and associated with a signal level generated by the signal generator circuit; and
regression circuitry, having an input coupled to an output of the accumulator circuitry, and an output coupled to the second input of the correction circuitry.

2. The analog-to-digital converter of claim 1, wherein the signal generator circuit comprises a dither generator circuit.

3. The analog-to-digital converter of claim 1, wherein the first stage ADC comprises:
a first adder having a first input coupled to the first input of the first stage ADC, a second input, and having an output coupled to the input of the residue amplifier;
a second adder having a first input coupled to the first input of the first stage ADC, a second input coupled to the output of the signal generator circuit, and having an output;
an ADC having an input coupled to the output of the second adder, and having an output at the digital output of the first ADC stage; and
a digital-to-analog converter (DAC), having an input coupled to the output of the ADC and an output coupled to the second input of the first adder.

4. The analog-to-digital converter of claim 3, wherein the first ADC stage further comprises:
a third adder having a first input coupled to the output of the first ADC, a second input coupled to the output of the signal generator circuit, and an output coupled to the input of the DAC.

5. The analog-to-digital converter of claim 1, wherein the selected input level detector comprises a stochastic comparator.

6. The analog-to-digital converter of claim 5, wherein the stochastic comparator comprises:
a first comparator, having a first input coupled to the input of the first ADC stage, a second input coupled to a threshold input, and having an output;
a second comparator, having a first input coupled to the input of the first ADC stage, a second input coupled to the threshold input, and having an output; and
a logic gate, having a first input coupled to the output of the first comparator, a second input coupled to the output of the second comparator, and an output coupled to the input of the accumulator circuitry.

7. The analog-to-digital converter of claim 6, wherein the logic gate is an exclusive-OR gate.

8. The analog-to-digital converter of claim 1, wherein the regression circuitry comprises polynomial regression logic;
and wherein the correction circuitry is capable of applying a correction at the output of the second ADC stage corresponding to non-linear terms in a polynomial computed by the regression circuitry.

9. The analog-to-digital converter of claim 1, further comprising:
a sample-and-hold circuit, having an input receiving an analog signal, and an output coupled to the first input of the first ADC stage and the input of the selected input level detector.

10. An analog-to-digital converter (ADC), comprising:
a signal generator circuit capable of providing a signal at a plurality of known signal levels;
a first ADC stage having a first input receiving an input signal, a second input receiving the dither signal, a first output presenting a first digital signal, and a second output presenting a residue signal;
a stochastic comparator, having an input coupled to the first input of the first ADC stage, and an output presenting a first signal indicating that the input signal is at a selected input level;
a residue amplifier, having an input receiving the residue signal from the first ADC stage;
a second ADC stage, having an input coupled to an output of the residue amplifier;
a correction circuit capable of applying a correction at an output of the second ADC stage to produce a second digital signal;
accumulator circuitry comprising a plurality of accumulators, each accumulator capable of accumulating the second digital signal for one or more of the plurality of known signal levels responsive to the first signal from the selected input level detector; and
regression circuitry capable of generating the correction applied by the correction circuit responsive to the contents of the plurality of accumulators.

11. The analog-to-digital converter of claim 10, wherein the signal generator circuit comprises a dither generator circuit capable of providing a dither signal at a plurality of known dither levels;
wherein each accumulator is capable of accumulating the second digital signal for one or more of the plurality of dither levels responsive to the first signal from the selected input level detector.

12. The analog-to-digital converter of claim 11, wherein the first stage ADC comprises:
a first adder capable of summing the input signal with the dither signal;
an ADC capable of digitizing the summed input and dither signals to produce the first digital signal;
a digital-to-analog converter (DAC) capable of providing an analog signal responsive to the first digital signal; and
a second adder capable of providing, to the residue amplifier, a sum of the analog signal with the input signal.

13. The analog-to-digital converter of claim 12, wherein the first ADC stage further comprises:
a third adder having a first input coupled to the output of the ADC, a second input receiving the dither signal, and an output coupled to an input of the DAC.

14. The analog-to-digital converter of claim 10, wherein the stochastic comparator generates the first signal based on an exclusive-OR of the outputs of a first and second comparators, each of the first and second comparators having a first input coupled to the input of the first ADC stage and a second input coupled to a threshold input.

15. The analog-to-digital converter of claim 10, wherein the regression circuitry is capable of performing a polynomial regression based on the accumulated contents of the plurality of accumulators;
and wherein the correction circuitry applies a correction at the output of the second ADC stage corresponding to non-linear terms in a polynomial computed by the regression circuitry.

16. The analog-to-digital converter of claim 10, further comprising:
a sample-and-hold circuit capable of providing a sampled signal as the input signal.

17. A method, comprising, for each of a plurality of input samples:
generating a signal at one of a plurality of known levels;
at a first analog-to-digital converter (ADC) stage, converting a summed signal of an input sample and a known level to m output bits and a residue;
at a second ADC stage, converting the residue from the first ADC stage to a second stage output;
responsive to the input sample being near a selected input level, adding the second stage output to the contents of one of a plurality of accumulators associated with the known level; and
applying an error correction to the second stage output based on the contents of the plurality of accumulators.

18. The method of claim 17, wherein generating a signal at one of a plurality of known levels comprises generating a dither signal at one of a plurality of dither levels.

19. The method of claim 17, wherein the adding of the second stage output to the contents of the one of the plurality of accumulators is responsive to the analog input sample being near a selected input level in combination with the m output bits from the first ADC stage corresponding to a digital value for the selected input level.

20. The method of claim 17, wherein the applying of the nonlinear error correction comprises:
performing a polynomial regression based on the contents of the plurality of accumulators;
wherein the error correction corresponds to one or more nonlinear terms of the polynomial regression.

21. The method of claim 17, further comprising:
applying the input sample to a first input of each of first and second comparators, each of the first and second comparators having a second input receiving a first threshold level;
responsive to outputs of the first and second comparators differing for an input sample, generating an indicator signal indicating that the input sample is near the first threshold level;
wherein the adding the second stage output to the contents of the one of a plurality of accumulators is performed responsive to the indicator signal.

22. The method of claim 21, wherein a plurality of input samples are applied to the first and second comparators while the first and second comparators receive the first threshold level;
and further comprising:
applying a plurality of input samples to the first and second comparators while the first and second comparators receive a second threshold level; and
responsive to outputs of the first and second comparators differing for an input sample, generating an indicator signal indicating that the input sample is near the second threshold level;
wherein the adding the second stage output to the contents of the one of a plurality of accumulators is performed responsive to the indicator signal.

23. The method of claim 17, further comprising:
amplifying the residue from the first ADC stage;
wherein converting the residue the first ADC stage comprises converting the amplified residue from the first ADC stage.
